(19) United States
(12) Patent Application Publication
(10) Pub. No.: US 2016/0099033 A1
(43) Pub. Date: Apr. 7, 2016

(54) COLUMN DECODER CIRCUITRY FOR A NON-VOLATILE MEMORY

(71) Applicants: STMICROELECTRONICS INTERNATIONAL N.V., Amsterdam (NL); STMICROELECTRONICS S.R.L., Agrate Brianza (IT)

(72) Inventors: Abhishek Lal, Faridabad (IN); Vikas Rana, Noida (IN); Marco Pasotti, Travaco' Sicomario (IT)

(73) Assignees: STMICROELECTRONICS INTERNATIONAL N.V., Amsterdam (NL); STMICROELECTRONICS S.R.L., Agrate Brianza (IT)

(21) Appl. No.: 14/506,865

(22) Filed: Oct. 6, 2014

(51) Int. Cl. G11C 8/10; G11C 8/18; G11C 7/22; G11C 7/06; G11C 7/10

(52) U.S. Cl. CPC G11C 8/10; G11C 7/06; G11C 7/10; G11C 7/22; G11C 8/18

(57) ABSTRACT

A memory includes a column decoder performing at least two levels of decoding using a first level decoder that decodes between the column bit lines and first level decode lines and a second level decoder that decodes between the first level decode lines and second level decode lines. The second level decoder includes first transistors coupled between the first level decode lines and read output lines and second transistors coupled between the first level decode lines and write input lines. The first transistors have a first voltage rating and are driven by decode control signals referenced to a low supply voltage compatible with the first voltage rating. The second transistors have a second voltage rating, higher than the first voltage rating, and are driven by decode control signals referenced to a high supply voltage (in excess of the low supply voltage) compatible with the second voltage rating.

### TECHNICAL FIELD

This disclosure relates generally to memory circuits, and more particularly to column decoder circuitry for use in a memory circuit of a non-volatile type.

### BACKGROUND

Non-volatile memory circuits are well known to those skilled in the art. In evaluating the operation of such a memory circuit, consideration is given to determining the power consumed during a memory read operation. This operational characteristic is an important figure of merit (FoM) for the memory circuit. Effort is accordingly made by the memory designer to minimize the power consumption value, especially during read mode, because non-volatile memories are often used in battery-powered devices and conservation of power is critical to extending the operating time of the device.

A significant portion of the power consumed during a memory read operation is due to the dynamic power consumption resulting from switching operations. In particular, the switching between different column multiplexers (col-mux decoding) can consume significant amounts of power. It is also noted that the column decoder circuitry passes high voltage levels during certain memory operations (such as erase mode). The transistors included in the column decoder circuitry thus must comprise high voltage rated devices which may contribute to reduced circuit performance during read operation. There is accordingly a need in the art for more efficient column decoding circuitry.

### SUMMARY

In an embodiment, a circuit comprises: a memory array including a plurality of column bit lines; and a column decoder circuit coupled to the plurality of column bit lines. The column decoder circuit includes at least two levels of decoding comprising: a first level decoder configured to decode between the plurality of column bit lines and a plurality of first level decode lines; and a second level decoder configured to decode between the plurality of first level decode lines and a plurality of second level decode lines. The second level decoder comprises: a set of first transistors coupled between the plurality of first level decode lines and read output lines; and a set of second transistors coupled between the plurality of first level decode lines and write input lines; wherein said first transistors have a first voltage rating and said second transistors have a second voltage rating higher than said first voltage rating.

In an embodiment, a circuit includes a column decoder operable to perform at least two levels of decoding. The column decoder comprises: a first level decoder configured to decode between a plurality of column bit lines and a plurality of first level decode lines in response to a first level decode signal; and a second level decoder. The second level decoder comprises: a read decoder including a set of first transistors coupled between the plurality of first level decode lines and a plurality of read output lines, said first transistors controlled by a second level decode signal referenced to a relatively low supply voltage; and a write decoder including a set of second transistors coupled between the plurality of first level decode lines and a plurality of write output lines, said second transistors controlled by said second level decode signal referenced to a relatively high supply voltage in excess of said relatively low supply voltage.

In an embodiment, a method for multi-level decoding of column bit lines of a memory array comprises: first level decoding between a plurality of column bit lines and a plurality of first level decode lines in response to a first level decode signal; and second level decoding of the first level decode lines. The second level decoding comprises: read decoding using first transistors coupled between the plurality of first level decode lines and a plurality of read output lines by controlling said first transistors with a second level decode signal referenced to a relatively low supply voltage; and write decoding using second transistors coupled between the plurality of first level decode lines and a plurality of write output lines by controlling said second transistors with said second level decode signal referenced to a relatively high supply voltage in excess of said relatively low supply voltage.

In an embodiment, a method for multi-level decoding of column bit lines of a memory array comprises: first level decoding between a plurality of column bit lines and a plurality of first level decode lines in response to a first level decode signal; and second level decoding of the first level decode lines. The second level decoding comprises: read decoding using first transistors coupled between the plurality of first level decode lines and a plurality of read output lines, said first transistors having a first voltage rating; and write decoding using second transistors coupled between the plurality of first level decode lines and a plurality of write output lines, said second transistors have a second voltage rating higher than said first voltage rating.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a simplified schematic diagram of a non-volatile memory including column decoder circuitry;

FIG. 2 is a schematic diagram of a two-level architecture for a column decoder circuit for use, for example, in the memory of FIG. 1;

FIG. 3 is a circuit diagram of a portion of the two-level architecture shown in FIG. 2;

FIG. 4 is a circuit diagram of a portion of an alternate embodiment for a portion of the two-level architecture shown in FIG. 2;

FIG. 5 illustrates an example of the biasing of the circuitry for the column decoder circuit of FIG. 4 in read and erase verify modes;

FIG. 6 illustrates an example of the biasing of the circuitry for the column decoder circuit of FIG. 4 in deep verify and program verify modes;

FIG. 7 illustrates an example of the biasing of the circuitry for the column decoder circuit of FIG. 4 in program and soft-program modes; and

FIG. 8 illustrates an example of the biasing of the circuitry for the column decoder circuit of FIG. 4 in erase mode.

### DETAILED DESCRIPTION OF THE DRAWINGS

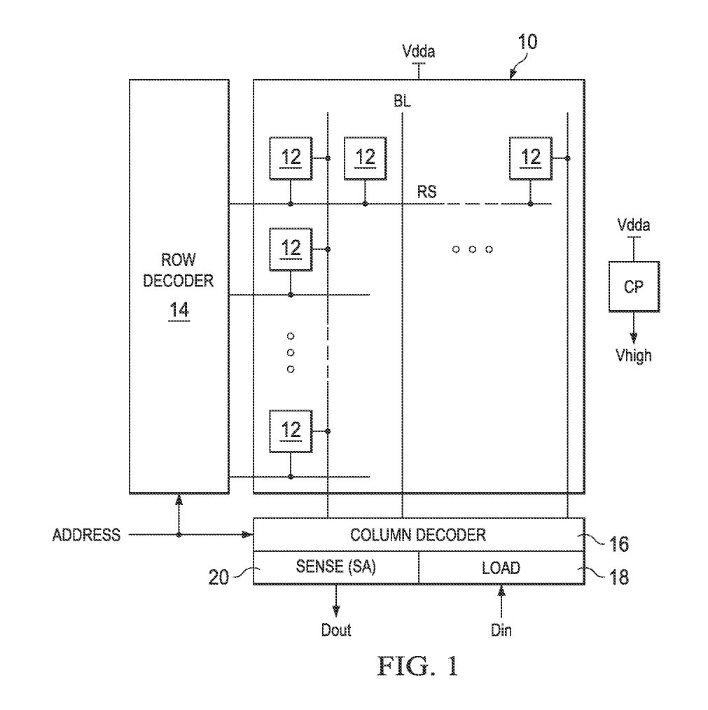

Reference is now made to FIG. 1 showing a simplified schematic diagram of a memory. The memory includes an array 10 of a memory cells 12 arranged in a column-row format. The memory cells 12 may comprise, for example, any suitable non-volatile memory circuit format (such as ROM or flash, for example). Each row of the memory includes a row select line (RS) coupled to an enable port of each memory cell 12 of the row. Actuation of the memory cell through its enable port permits data to be written into or read from the memory cell. The set of row select lines for the memory are coupled to the output a row decoder circuit 14. In response to a received address, the row decoder circuit 14 selects one of the row select lines for actuation. Each column of the memory includes a local bit line BL coupled to a corresponding data port of each memory cell 12 of the column. The local bit lines BL are coupled to a column decoder circuit 16. In write mode, a load circuit 18 applies data (Din) to the column decoder circuit 16. The column decoder circuit 16 responds to the received address and selects the bit lines BL for columns to which the data is to be applied for writing into the corresponding memory cells 12 at the actuated row. In a read mode, the column decoder circuit 16 responds to the received address and selects the bit lines BL for columns from which data is to be read. The data stored in the memory cells at the addressed columns and row is passed from the bit lines BL to a sense circuit 20 for detection and data output (Dout).

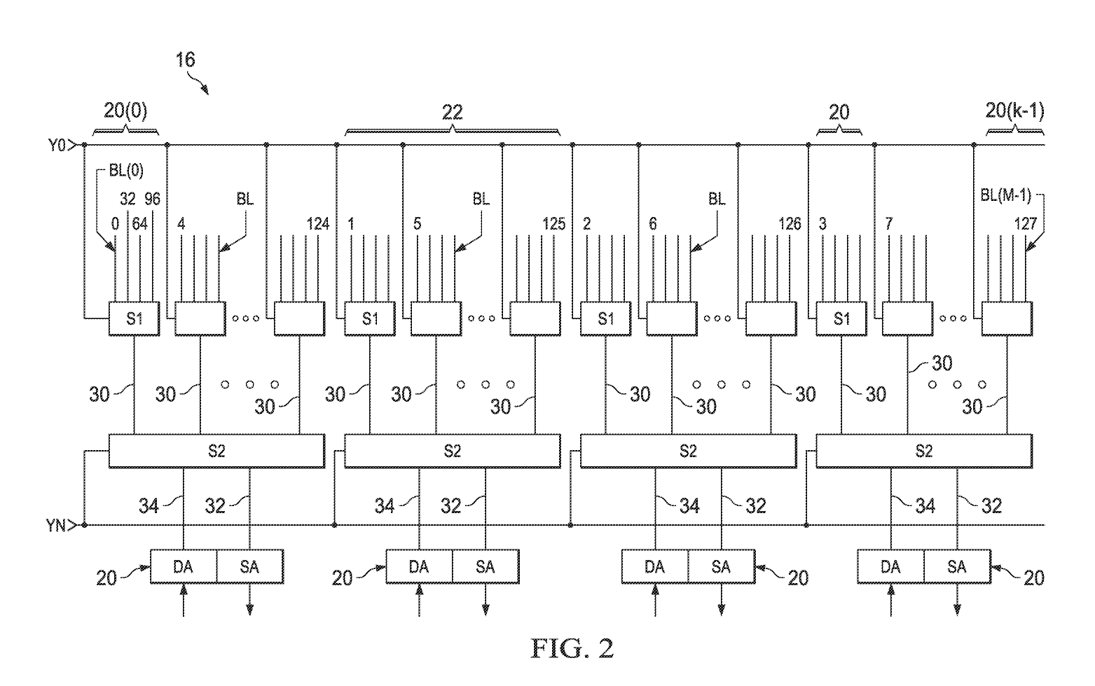

Reference is now made to FIG. 2 showing a schematic diagram of a two-level architecture for a column decoder circuit 16 like that used in the memory of FIG. 1. The memory array 10 includes M columns. Thus, there will be M bit lines (BL(0)-BL(M-1)). In the example shown in FIG. 2, M=128 but it will be understood that this is just an example and the circuitry described herein is compatible with memories of varying size, both larger and smaller than that illustrated in FIG. 2. The bit lines are arranged in groups 20. In the illustrated example, each group 20 includes four bit lines, and thus there are K=M/4=32 groups 20, with a first group 20(0) of bit lines BL including, in this example, the bit lines numbered 0, 32, 64 and 96. The last group 20(K-1) includes the last bit line BL(M-1). The groups 20 are arranged together to form a plurality of pages 22. In this example, each page 22 includes eight groups 20, and thus there are L=K/8=4 pages.

A first level of decoding is performed by the column decoder circuit 16 through a plurality of first level decoder circuits S1 (equal in number to the number of groups 20). Each decoder circuit S1 is coupled on one side to a group 20 of bit lines BL and coupled on the other side to a first level decode line 30. Each first level decoder circuit S1 performs multiplexing/demultiplexing operation between the connected bit lines BL and the first level decode line 30 in response to a first level control signal YO. The signal YO is a multibit signal derived from the address (for example, comprising certain bits of the address). The signal YO is configured to control the multiplexing/demultiplexing operation in each circuit Si to select only one of the bit lines BL at a time for coupling to the first level decode line 30.

A second level of decoding is performed by the column decoder circuit 16 through a plurality second level decoder circuits S2 (equal in number to the number of pages 22). Each decoder circuit S2 is coupled on one side to a group of first level decode lines 30 and coupled on the other side to a second level read decode line 32 and a second level write decode line 34. Each second level decoder circuit S2 performs multiplexing/demultiplexing operation between the connected first level decode lines 30 and the second level decode lines 32/34 in response to a second level control signal YN. The signal YN is a multibit signal derived from the address (for example, comprising certain bits of the address). The signal YN is configured to control the multiplexing/demultiplexing operation in each circuit S2 to select only one of the first level decode lines 30 at a time for coupling to the second level decode line 32/34. Each second level read decode line 32 is coupled to a sense amplifier (SA) of the sense circuit 20. Each second level write decode line 34 is coupled to a drive amplifier (DA) of the load circuit 18.

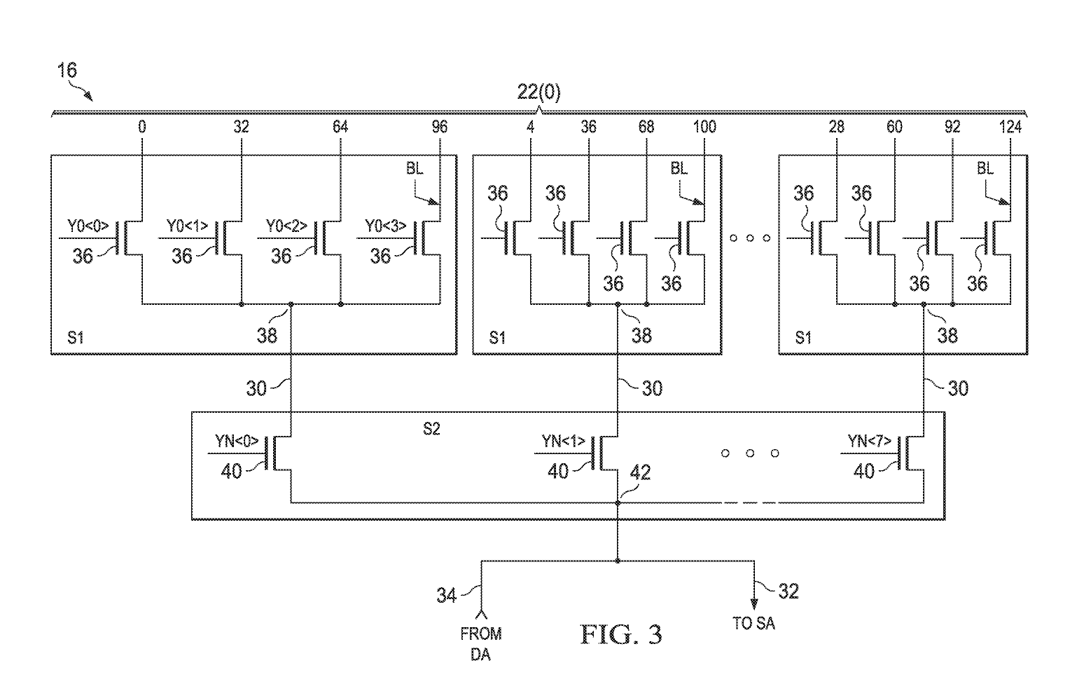

Reference is now made to FIG. 3 showing a circuit diagram of a portion of the two-level architecture of the column decoder 16 shown in FIG. 2. The illustrated portion in FIG. 3 concerns the first page 22(0) of the memory, it being understood that this circuitry is replicated for each page.

Each decoder circuit S1 comprises a plurality of first transistors 36. The transistors 36 are n-channel MOSFET devices. The drain terminal of each transistor 36 is coupled to a bit line BL. The source terminals of the transistors 36 in each decoder circuit S1 are coupled together at a common node 38 corresponding to the first level decode line 30. The gate terminals of the transistors 36 are coupled to receive the first level control signal YO. In this configuration, each transistor 36 in a given decoder circuit S1 receives a different bit of the first level control signal YO. So, for example, the first transistor 36 in each circuit S1 is gate controlled by the first bit YO<0> of the first level control signal YO, the second transistor each circuit S1 is gate controlled by the second bit YO<1>, and so on. The individual transistors 36 function as pass-gate devices and are actuated in response to a logic high state of the corresponding control signal YO bit to permit passage of data between a selected one of the bit lines BL and the common node 38.

Each decoder circuit S2 comprises a plurality of second transistors 40. The transistors 40 are n-channel MOSFET devices. The drain terminal of each transistor 40 is coupled to one of the first level decode lines 30. The source terminals of the transistors 40 in each decoder circuit S2 are coupled together at a common node 42 corresponding to the second level decode lines 32/34. The gate terminals of the transistors 40 are coupled to receive the second level control signal YN. In this configuration, each transistor 40 in a given decoder circuit S2 receives a different bit of the second level control signal YN. So, for example, the first transistor 40 in each circuit S2 is gate controlled by the first bit YN<0> of the second level control signal YN, the second transistor each circuit S2 is gate controlled by the second bit YN<1>, and so on. The individual transistors 40 function as pass-gate devices and are actuated in response to a logic high state of the corresponding control signal YN bit to permit passage of data between a selected one of the first level decode lines 30 and the common node 42.

The transistors 36 and 40 used in the circuits S1 and S2 are typically higher voltage rated transistors because the decoder circuit 16 must be capable of handling large voltages in certain operating modes of the memory (for example, erase mode). Those skilled in the art understand that such higher voltage rated transistors have a lower transconductance (gm). The control signals YO and YN must thus utilize a relatively high voltage (Vhigh) for logic high. In memory circuits like that shown in FIG. 1, however, the supply voltage for the memory array (for example, referred to as Vdda) is typically less than the required higher voltage for the control signals YO and YN. Thus, the memory must include a charge pump (CP) circuit configured to generate the higher supply voltage by pumping up from the lower voltage Vdda.

It is further noted that the dynamic power consumption of the higher voltage rated transistors 36 and 40 during switching is also relatively high due to high capacitance. The charge pump circuit for generating the required higher voltage Vhigh for the control signals YO and YN must be designed to support the higher power consumption.

In view of the foregoing, a memory which utilizes a column decoder circuit having the configuration shown in FIG. 3 will undesirably need a charge pump circuit occupying a large amount of chip space and further operate at an increased total dynamic power consumption (especially during read operations).

The following table illustrates the biasing required for operation of the memory with a column decoder 16 as shown in FIGS. 2 and 3:

| | Node 42 | YN | Node 38 | YO | BL | Pwell array | Pwell YO |
|---|---|---|---|---|---|---|---|
| Read | 0.6 | 4.5/0 | 0.6/flt | 4.5/0 | 0.6/flt | 0 | 0 |
| Program | 4.2 | 8.5/0 | 4.2/flt | 8.5/0 | 4.2/flt | 0 | 0 |
| Erase | 0.6 | 0/0 | flt-charge to | 8.5/0 | flt-charge to | 8.5 | 8.5 |
| | | | 8.0 by bulk | | 8.0 by bulk | | |

In this table, the bias numbers are in volts and “flt” means floating. The higher voltage Vhigh from the charge pump may be used to generate the 4.5V and 8.5V bias voltages.

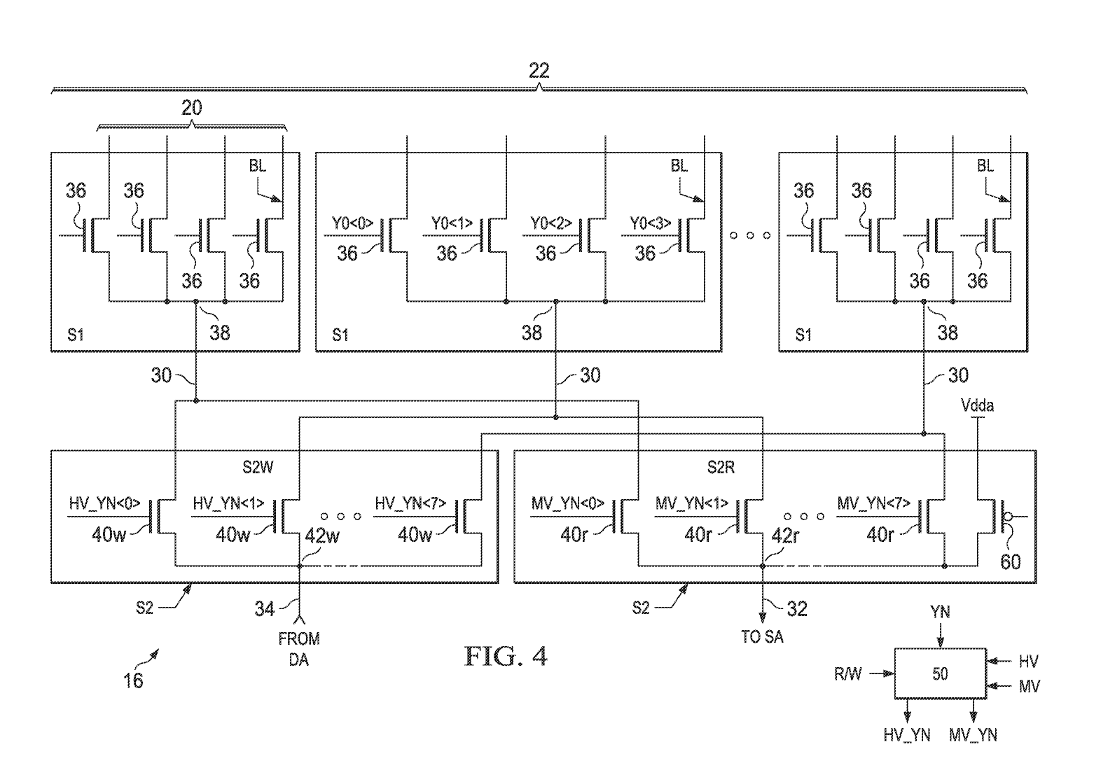

Reference is now made to FIG. 4 showing a circuit diagram of a portion of an alternate embodiment for the column decoder 16 of the two-level architecture. Like reference numbers refer to like or similar parts. The illustrated portion in FIG. 4 concerns one page 22 of the memory, it being understood that this circuitry is replicated for each page.

The implementation of FIG. 4 differs from the implementation of FIG. 3 in that each second level decoder circuit S2 is divided into a read second level decoder circuit S2R and a write second level decoder circuit S2W for reasons to be described herein.

Each read decoder circuit S2R comprises a plurality of second transistors 40r. The transistors 40r are n-channel MOSFET devices. The drain terminal of each transistor 40r is coupled to one of the first level decode lines 30. The source terminals of the transistors 40r in each decoder circuit S2R are coupled together at a common node 42r corresponding to the second level decode line 32. The gate terminals of the transistors 40r are coupled to receive the second level control signal YN. In this configuration, each transistor 40r in a given decoder circuit S2R receives a different bit of the second level control signal YN. So, for example, the first transistor 40r in each circuit S2R is gate controlled by the first bit MV_YN<0> of the second level control signal YN, the second transistor each circuit S2R is gate controlled by the second bit MV_YN<1>, and so on. The individual transistors 40r function as pass-gate devices and are actuated in response to a logic high state of the corresponding control signal YN bit to permit passage of data between a selected one of the first level decode lines 30 and the common node 42r.

Each write decoder circuit S2W comprises a plurality of second transistors 40w. The transistors 40w are n-channel MOSFET devices. The drain terminal of each transistor 40w is coupled to one of the first level decode lines 30. The source terminals of the transistors 40w in each decoder circuit S2W are coupled together at a common node 42w corresponding to the second level decode line 34. The gate terminals of the transistors 40w are coupled to receive the second level control signal YN. In this configuration, each transistor 40w in a given decoder circuit S2W receives a different bit of the second level control signal YN. So, for example, the first transistor 40w in each circuit S2W is gate controlled by the first bit HV_YN<0> of the second level control signal YN, the second transistor each circuit S2W is gate controlled by the second bit HV_YN<1>, and so on. The individual transistors 40w function as pass-gate devices and are actuated in response to a logic high state of the corresponding control signal YN bit to permit passage of data between a selected one of the first level decode lines 30 and the common node 42w.

The circuit configuration of FIG. 4 accordingly provides two parallel paths through the second level decoder circuit S2, one path using the read decoder circuit S2R (coupled to the sense amplifier (SA)) and another path using the write decoder circuit S2W (coupled to the drive amplifier (DA)). With this configuration, the transistors 40r in the read decoder circuit S2R do not need to be higher voltage rated transistors because they are not exposed to higher voltages during certain operating modes of the memory like erase mode. So, the transistors 40r in the read decoder circuit S2R are instead configured as lower (or medium) voltage rated transistors. The transistors 40w of the circuit S2W remain configured as higher voltage rated transistors like those transistors 40 of FIG. 3.

The read decoder circuit S2R and write decoder circuit S2W may in some modes be mutually exclusively actuated. Thus, during a read operation only the read decoder circuit S2R is active (transistors of the circuit S2W are not actuated). Conversely, during a write operation only the write decoder circuit S2W is active (transistors of the circuit S2R are not actuated). To accomplish this level of control, the gate drive signals for the transistors 40r and 40w must be separately generated responsive to the operating mode (read/write) of the memory. A control circuit 50 receives the second level control signal YN and a signal R/W indicative of whether the memory is in read or write mode. Responsive thereto, the circuit generates the output gate control signals MV_YN for application to the transistors 40r of the read decoder circuit S2R and further generates the output gate control signals HV_YN for application to the transistors 40w of the write decoder circuit S2R.

The circuit 50 further receives two supply voltages: a relatively higher voltage HV (for example, Vhigh or a voltage derived from Vhigh) and a relatively lower voltage MV (for example, Vdda). The higher voltage HV may, for example, and as described above, comprise a pumped voltage as needed to operate higher voltage rated transistors. The transistors 40w of the write decoder circuit S2W comprise such higher voltage rated transistors, and thus the circuit 50 uses the relatively higher voltage HV as the supply reference for generating the output gate control signals HV_YN for application to the transistors 40w of the write decoder circuit S2W. So, the output gate control signals HV_YN will have a logic level high voltage at the relatively higher voltage HV. The lower voltage MV may, for example, comprise a voltage compatible with operation of the lower voltage rated transistors. The transistors 40r of the read decoder circuit S2R comprise such lower voltage rated transistors, and thus the circuit 50 uses the relatively lower voltage MV as supply for generating the output gate control signals MV_YN for application to the transistors 40r of the read decoder circuit S2R. So, the output gate control signals MV_YN will have a logic level high voltage at the relatively lower voltage MV.

The following table illustrates the biasing required for operation of the memory with a column decoder as shown in FIGS. 2 and 4:

| | Node | | | | | | Pwell | Pwell |
|---|---|---|---|---|---|---|---|---|
| | 42/32 | HV_YN | MV_YN | Node 38 | YO | BL | array | YO |
| Read | 0.6 | 0/0 | Vdda/0 | 0.6/flt | 4.5/0 | 0.6/flt | 0 | 0 |
| Program | Vdda/0 | 8.5/0 | Vdda/0 | 4.2/flt | 8.5/0 | 4.2/flt | 0 | 0 |
| Erase | Vdda | 4.5/4.5 | Vdda/Vdda | 4.5-Vt | 4.4 | flt-charge | 8.5 | 0 |
| | | | | | | to 8.0 by | | |
| | | | | | | bulk | | |

In this table, the bias numbers are in volts, “flt” means floating, “Vt” is the transistor threshold voltage of the NMOS transistor use at the YO decoding stage, and “Vdda” is the lower voltage level MV. The higher voltage Vhigh from the charge pump may be used to generate the 4.5V and 8.5V bias voltages.

In comparing the circuit of FIG. 4 to the circuit of FIG. 3, it is noted that the transistors 40r comprise transistors with a relatively lower voltage rating than the transistors 40. Such lower voltage rated transistors 40r possess a lower threshold voltage (Vt) as compared to the threshold voltage of the transistors 40. Still further, the transistors 40r provide a better transconductance (gm). This allows the gate control signals MV_YN used to drive the transistors 40r to be referenced to a lower supply voltage (Vdda) than the signals YN driving the transistors 40 (or the signals HV_YN driving the transistors 40w) which are instead referenced to a higher supply voltage. As a result, dynamic power consumption during switching of the circuit S2 is provided directly from the Vdda supply. A smaller charge pump can then be provided for generating the high voltage (used as the reference for the signals HV_YN), and there is a reduction in the total dynamic power consumption for the circuit using the column decoder 16 of FIG. 4.

There is a cost to using the circuit design of FIG. 4 in that circuitry for the parallel paths for read and write must be provided at some increase in chip area. However, this area is small and is offset by the reduced size of the charge pump. An additional cost concerns ensuring the appropriate biasing of the circuit nodes as shown in the table above in order to prevent safe operating area (SOA) violations. A more detailed explanation of the required biasing is as follows:

Line 32; at the connection with the sense amplifier (SA), a p-channel MOSFET 60 is coupled between the lower voltage supply Vdda and the node 32. Actuation of this transistor 60 functions to bias the node 32 to Vdda whenever needed.

Additionally, the column decoder circuit 16 is configured so that the p-well of transistors 36 is disconnected from the p-well of the transistors for the memory cells 12 of the array 10. In the configuration of FIG. 3, the p-well for transistors 36 is connected to the array p-well, and thus during an erase operation the voltage (for example, 8.0V) applied to the p-well of the array is also applied to the p-well of transistors 36. As a result, the node 38 is also charged to that well bias voltage. In the configuration of FIG. 4, however, this bias voltage would appear at the drain of the lower voltage rating transistors 40r resulting in an SOA violation. To address this concern, the p-wells are disconnected from each other and the p-well for the transistors 40r is fixed at 0V for all operating modes.

In program mode, the line 30 is driven to a programming voltage (for example, 4.2V) or ground (0V) depending on the data output from the drive amplifier DA. So, the drain terminal of transistor 40r could be at 4.2V. To prevent an SOA violation, the gates of transistors 40r are all driven to Vdda, and the line 32 is accordingly biased to 4.2V/0V depending on the data being programmed. This further ensures that there is no static path from line 30 to line 32.

In erase mode, the lines 30 are all driven to 4.5V-Vt, so this voltage is present at the drains of transistors 40r. To ensure no SOA violation, the gates of the transistors 40r are all driven to Vdda, and the line 32 is accordingly biased to Vdda. This further ensures that there is no static path from line 30 to line 32.

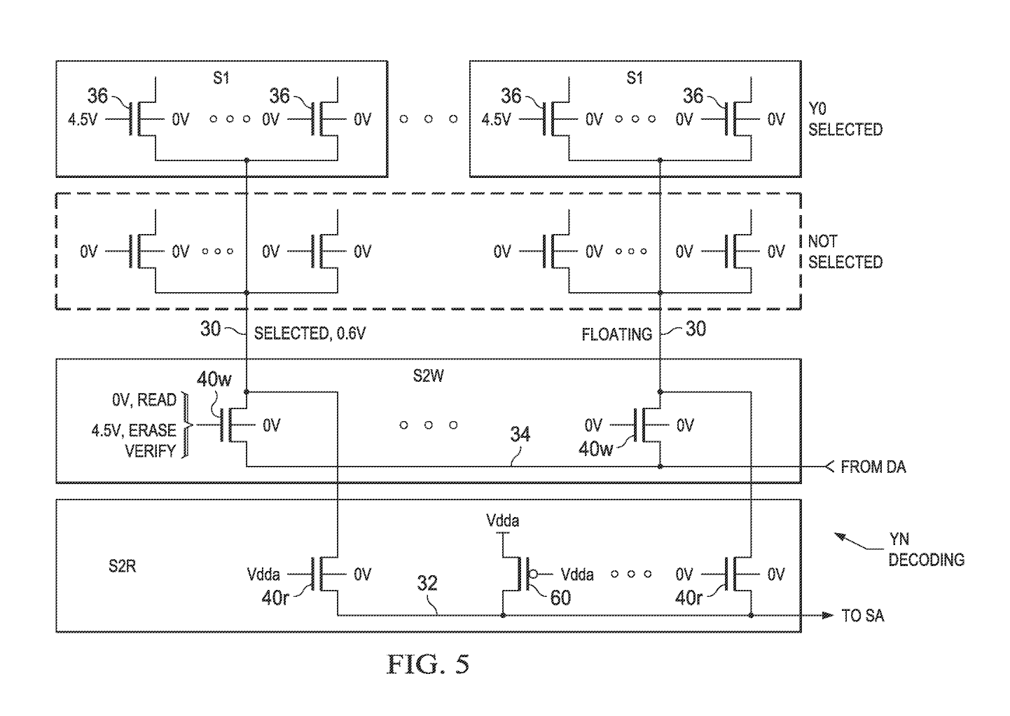

An example of the biasing of the circuitry for the column decoder of FIG. 4 in read and erase verify modes is shown in FIG. 5.

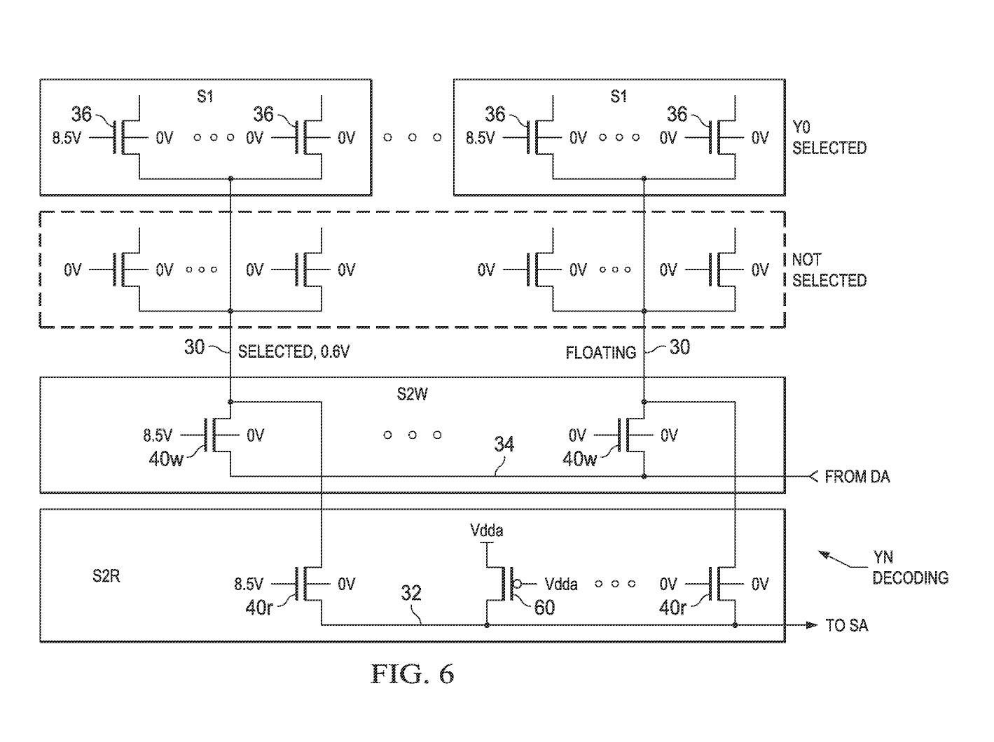

An example of the biasing of the circuitry for the column decoder of FIG. 4 in deep verify and program verify modes is shown in FIG. 6.

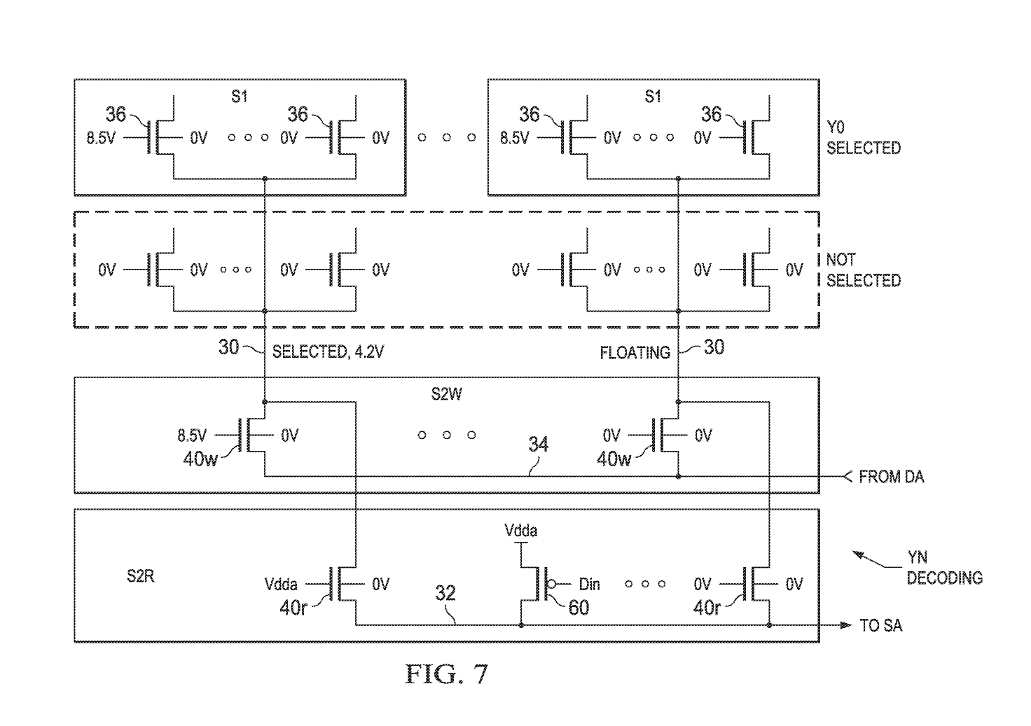

An example of the biasing of the circuitry for the column decoder of FIG. 4 in program and soft-program modes is shown in FIG. 7.

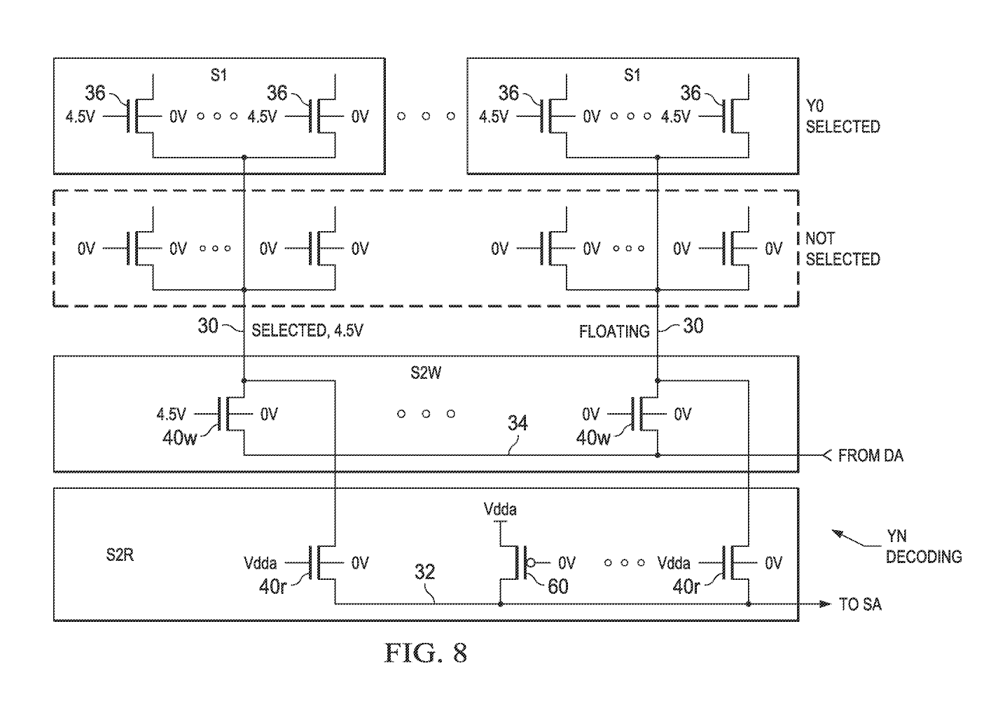

An example of the biasing of the circuitry for the column decoder of FIG. 4 in erase mode is shown in FIG. 8.

The examples of FIGS. 5-8 are non-limiting and provided solely to illustrate one set of biasing voltages.

A number of advantages accrue from the use of the circuit of FIG. 4: a reduction of overall dynamic consumption during sequential read; a reduction on current load of the charge pump; a limiting of the drain-to-source voltage for the transistors 36 of the circuit S1 permits the use of shorter gate length transistors with consequent improved performance in terms of power, circuit area and switching time; and a small area increase needed to support both circuits S2R and S2W is offset by the need for a charge pump occupying a smaller circuit area.

It will be readily understood by those skilled in the art that materials and methods may be varied while remaining within the scope of the present disclosure. It is also appreciated that the present disclosure provides many applicable inventive concepts other than the specific contexts used to illustrate embodiments. Accordingly, the appended claims are intended to include within their scope such processes, machines, manufacturing, compositions of matter, means, methods, or steps.

What is claimed is:

1. A circuit, comprising:
a memory array including a plurality of column bit lines; and
a column decoder circuit coupled to the plurality of column bit lines,
wherein the column decoder circuit includes at least two levels of decoding comprising:
a first level decoder configured to decode between the plurality of column bit lines and a plurality of first level decode lines; and
a second level decoder configured to decode between the plurality of first level decode lines and a plurality of second level decode lines; and
wherein said second level decoder comprises:
a set of first transistors coupled between the plurality of first level decode lines and read output lines;
a set of second transistors coupled between the plurality of first level decode lines and write input lines; and
said first transistors having a first voltage rating and said second transistors having a second voltage rating higher than said first voltage rating.

2. The circuit of claim 1, wherein said set of first transistors are controlled by a first decode signal that is logic high referenced to a relatively low supply voltage and said set of second transistors are controlled by a second decode signal that is logic high referenced to a relatively high supply voltage in excess of said relatively low supply voltage.

3. The circuit of claim 2, wherein said first level decoder is controlled in response to a first level decode signal derived from an address and said second level decoder is controlled in response to a second level decode signal also derived from said address.

4. The circuit of claim 3, wherein first decode signal is derived from said second level decode signal and wherein said second decode signal is derived from said second level decode signal.

5. The circuit of claim 2, wherein said memory array is powered from said relatively low supply voltage.

6. The circuit of claim 2, further comprising:
a signal generation circuit including inputs to receive said relatively low supply voltage, said relatively high supply voltage and a second level decode signal derived from an address;
wherein said signal generation circuit is configured to generate said first decode signal from the second level decode signal, the first decode signal having a high logic level defined by said relatively low supply voltage; and
wherein said signal generation circuit is configured to generate said second decode signal from the second level decode signal, the second decode signal having a high logic level defined by said relatively high supply voltage.

7. The circuit of claim 6, wherein the inputs of said signal generation circuit further receive a read/write signal indicating whether said memory array is operating in read or write mode, and wherein said signal generation circuit is configured to generate an active first decode signal only when the memory array is in read mode and generate an active second decode signal only when the memory array is in write mode.

8. The circuit of claim 2, further comprising a bias transistor coupled between the relatively low supply voltage and each read output line, said bias transistors selectively actuated to bias the read output lines to the relatively low supply voltage in a certain operating mode of the memory array.

9. The circuit of claim 8, wherein the certain operating mode is an erase mode.

10. A circuit including a column decoder operable to perform at least two levels of decoding, comprising:
a first level decoder configured to decode between a plurality of column bit lines and a plurality of first level decode lines in response to a first level decode signal; and
a second level decoder comprising:
a read decoder including a set of first transistors coupled between the plurality of first level decode lines and a plurality of read output lines, said first transistors controlled by a second level decode signal referenced to a relatively low supply voltage; and
a write decoder including a set of second transistors coupled between the plurality of first level decode lines and a plurality of write output lines, said second transistors controlled by said second level decode signal referenced to a relatively high supply voltage in excess of said relatively low supply voltage.

11. The circuit of claim 10, further comprising:
a sense amplifier having an input coupled to each of the read output lines; and
a drive amplifier having an output coupled to each of the write output lines.

12. The circuit of claim 10, wherein said first transistors have a first voltage rating compatible with said low supply voltage and said second transistors have a second voltage rating higher than said first voltage rating compatible with said high supply voltage.

13. The circuit of claim 10, wherein said first level decode signal is derived from a first portion of an address and said second level decode signal is derived from a second portion of said address.

14. The circuit of claim 10, further comprising a bias transistor coupled between the relatively low supply voltage and each read output line, said bias transistors selectively actuated to bias the read output lines to the relatively low supply voltage.

15. A method for multi-level decoding of column bit lines of a memory array, comprising:
first level decoding between a plurality of column bit lines and a plurality of first level decode lines in response to a first level decode signal; and
second level decoding of the first level decode lines, said second level decoding comprising:
read decoding using first transistors coupled between the plurality of first level decode lines and a plurality of read output lines by controlling said first transistors with a second level decode signal referenced to a relatively low supply voltage; and
write decoding using second transistors coupled between the plurality of first level decode lines and a plurality of write output lines by controlling said second transistors with said second level decode signal referenced to a relatively high supply voltage in excess of said relatively low supply voltage.

16. The method of claim 15, wherein said first transistors have a first voltage rating compatible with said low supply voltage and said second transistors have a second voltage rating higher than said first voltage rating compatible with said high supply voltage.

17. The method of claim 15, further comprising deriving said first level decode signal from a first portion of an address and deriving said second level decode signal from a second portion of said address.

18. A method for multi-level decoding of column bit lines of a memory array, comprising:
first level decoding between a plurality of column bit lines and a plurality of first level decode lines in response to a first level decode signal; and
second level decoding of the first level decode lines, said second level decoding comprising:
read decoding using first transistors coupled between the plurality of first level decode lines and a plurality of read output lines, said first transistors having a first voltage rating; and
write decoding using second transistors coupled between the plurality of first level decode lines and a plurality of write output lines, said second transistors have a second voltage rating higher than said first voltage rating.

19. The method of claim 18,
wherein read decoding comprises controlling said first transistors with a second level decode signal having a logic high referenced to a relatively low supply voltage compatible with said first voltage rating; and
wherein write decoding comprises controlling said second transistors with said second level decode signal having a logic high referenced to a relatively high supply voltage, in excess of said relatively low supply voltage, compatible with said second voltage rating.

20. The method of claim 19, further comprising deriving said first level decode signal from a first portion of an address and deriving said second level decode signal from a second portion of said address.
